(19) United States
(12) Patent Application Publication
(10) Pub. No.: US 2017/0032960 A1
(43) Pub. Date: Feb. 2, 2017

(54) COMPOSITION FOR COATING PHOTORESIST PATTERN AND METHOD FOR FORMING FINE PATTERN USING THE SAME

(71) Applicant: SK hynix Inc., Gyeonggi-do (KR)

(72) Inventors: Sung Jae Lee, Gyeonggi-do (KR); Keun Kyu Kong, Seoul (KR); Jeong Hoon An, Gyeonggi-do (KR); Yun Seop Oh, Gyeonggi-do (KR); Chang Yeol Oh, Gyeonggi-do (KR)

(21) Appl. No.: 14/992,401

(22) Filed: Jan. 11, 2016

(30) Foreign Application Priority Data
Jul. 27, 2015 (KR) 10-2015-0106077

(51) Int. Cl. H01L 21/027; C09D 4/00

(52) U.S. Cl. CPC H01L 21/0273; C09D 4/00

(57) ABSTRACT

Disclosed are a composition for coating a photoresist pattern and a method for forming a fine pattern using the same. The composition for coating a photoresist pattern includes an ammonium base-containing polymer compound and a solvent. The method for forming a fine pattern includes coating the composition on a previously formed photoresist pattern to thereby effectively reduce the size of a photoresist contact hole or space, and can be used in all semiconductor processes in which a fine pattern is required to be formed.

### CROSS-REFERENCES TO RELATED APPLICATION

The present application claims priority under 35 USC. §119(a) to Korean application number 10-2015-0106077, flied on Jul. 27, 2015, which is herein incorporated by reference in its entirety.

### BACKGROUND

1. Technical Field

Various embodiments generally relate to a composition for coating a photoresist pattern and a method for forming a fine pattern using the same.

2. Related Art

In recent years, technology for fabricating semiconductor devices has been developing rapidly and the fields of application of semiconductor memory devices have been expanded dramatically. At the same time, development of improved lithography processes including the development of photoresist materials, new light sources, and light exposure systems has allowed the development of semiconductor memory devices having increased integration density. A maximum resolution obtainable by use of existing exposure systems, such as KrF and ArF exposure systems is limited to about 0.1 μm, making difficult to form a pattern smaller than this limit in order to fabricate a highly integrated semiconductor device. Hence further improvements are desirable in order to obtain semiconductor memory devices having even higher integration densities.

To address this issue, a method is provided that is capable of overcoming the resolution limit of conventional photoresist patterns and forming a fine pattern without using expensive materials and complex process steps.

### SUMMARY

Various embodiments are directed to a composition for coating a photoresist pattern (hereinafter also referred to as the “photoresist pattern coating composition”), which includes: an ammonium base-containing polymer compound capable of reacting with a photoresist material to form a coating film on the surface of the photoresist material; and a solvent.

Specifically, a composition for coating a photoresist pattern, comprising a polymer compound and a solvent, wherein the polymer compound is represented by the following formula 1:

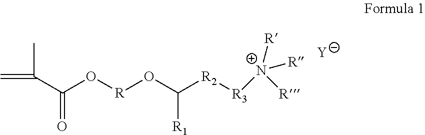

wherein R is a non-substituted or substituted, linear or branched hydrocarbon group having 1 to 20 carbon atoms or a non-substituted or substituted, cyclic hydrocarbon group having 3 to 20 carbon atoms; wherein R₁ is hydrogen, a linear or branched hydrocarbon group having 1 to 5 carbon atoms, or an oxygen atom and when R₁ is an oxygen atom, it forms a double bond with a carbon atom;
wherein R₂ is oxygen or a linear or branched hydrocarbon group having 1 to 5 carbon atoms;
wherein R₃ is a linear or branched hydrocarbon group having 1 to 5 carbon atoms;
wherein each of R′ R′ and R′″ is independently hydrogen or a linear or branched hydrocarbon group having 1 to 5 carbon atoms; and
wherein Y⁻ is at least one anion selected from the group consisting of F⁻, Cl⁻, Br⁻, I⁻, NO₃⁻, HsO₄⁻, BF₄⁻, CN⁻, SO₃CF₃⁻, carbonate (COO⁻), sulfonate (SO₃⁻), sulfate (SO₄⁻), phosphonate (PO₃⁻), and phosphate (PO₄⁻).

The polymer compound is represented by the following formula 1a:

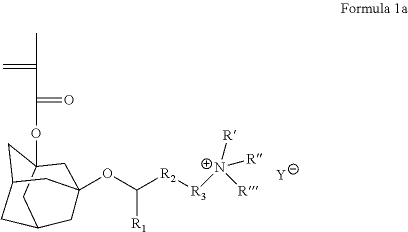

wherein R₁ is hydrogen a linear or branched hydrocarbon group having 1 to 5 carbon atoms, or an oxygen atom, and when R₁ is an oxygen atom, it forms a double bond with a carbon atom;
wherein R₂ is oxygen or a linear or branched hydrocarbon group having 1 to 5 carbon atoms;
wherein R₃ is a linear or branched hydrocarbon group having 1 to 5 carbon atoms;
wherein each of R′, R″ and R′″ each independently hydrogen or a linear or branched hydrocarbon group having 1 to 5 carbon atoms; and
Y⁻ is at least one anion selected from the group consisting of F⁻, Cl⁻, Br⁻, I⁻, NO₃⁻, HSO₄⁻, BF₄⁻, CN⁻, SO₃CF₃⁻, carbonate (COO⁻), sulfonate (SO₃⁻) sulfate (SO₄⁻), phosphonate (PO₃⁻), and phosphate (PO₄⁻).

The polymer compound is represented by the following formula 1b or 1c:

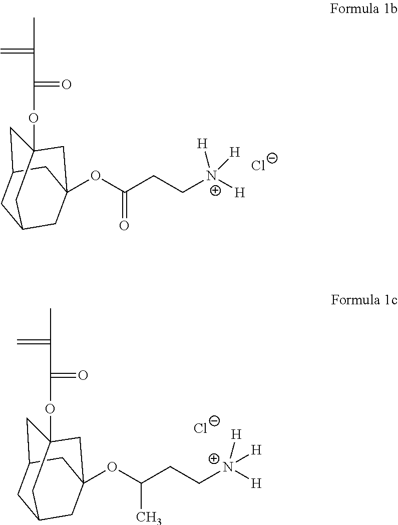 [SMILES: C=C(C)C(=O)OC12CC3CC(CC(OC(=O)CC[NH3+])(C3)C1)C2 ; [Cl-] ; C=C(C)C(=O)OC12CC3CC(C1)CC(OC(C)CC[NH3+])(C3)C2 ; [Cl-]]

The polymer compound represented by formula 1 is contained in an amount of 0.1-3 wt % based on the total weight of the composition, The solvent comprises an alcohol. The composition further includes a surfactant. The alcohol is selected from the group consisting of a C₁-C₁₀ alkylalcohol, a C₂-C₁₀ alkoxy alkylalcohol, and a combination thereof. The C₁-C₁₀ alkylalcohol is selected from the group consisting of methanol, ethanol, propanol, isopropanol, n-butanol, sec-butanol, t-butanol 1-pentano, 2-pentanol, 3-pentanol, and 2,2-dimethyl-1-propanol and a combination thereof. The C₂-C₁₀ alkoxy alkylalcohol is selected from the group consisting of 2-methoxyethanol, 2-(2-methoxyethoxy)ethanol, 1-methoxy-2-propanol, 3-methoxy-1,2-propanoldiol, and a combination thereof. The surfactant is contained in an amount of from 0.001 to 0.1 wt % based on the total weight of the composition.

Other embodiments are directed to a method for forming a fine pattern, which includes coating the photoresist pattern coating composition on a previously formed photoresist pattern to thereby effectively reduce the size of a photoresist contact hole or space, and is applicable to all devices in which a fine pattern is required to be formed.

Specifically, a method for forming a fine pattern, comprising: forming a first photoresist pattern over a underlying layer; coating the composition of the present invention over first photoresist pattern to form a composition layer; baking the photoresist pattern and the composition to form a coating layer at an interface between the first photoresist pattern and the composition layer; and removing an unreacted portion of the composition layer to form a second photoresist pattern.

The second photoresist pattern comprises the coating layer and the first photoresist pattern. The space between two neighboring second photoresist patterns is a smaller than the space between two neighboring first photoresist patterns. The baking is performed at a temperature ranging from 100° C. to 200° C.

The removing of the unreacted portion of the composition layer is performed using water or an alkaline developer. The first photoresist pattern has a width of 30 to 300 nm. The second photoresist pattern has a width which is 10-40% greater than the width of the first photoresist pattern, and wherein the space between two neighboring second photoresist patterns is a smaller than the space between two neighboring first photoresist patterns. The coating layer has a thickness of from 300 to 3000 Å.

A device comprising: a substrate; and a photoresist pattern formed over the substrate by the method of the present invention. The photoresist pattern is coated by a coating layer, and wherein the coating layer comprises the compound represented by the formula 1.

### BRIEF DESCRIPTION OF THE DRAWINGS

FIGS. 1 to 3 are schematic views illustrating a method for forming a fine photoresist pattern using a composition according to an embodiment of the invention.

FIG. 4 is a photograph of a photoresist pattered formed according to a Comparative Example.

FIG. 5 is a photograph of a photoresist pattern formed according to Example 3.

FIG. 6 is a photograph of a photoresist pattern formed according to Example 4.

### DETAILED DESCRIPTION

Hereinafter, a composition for coating a photoresist pattern and in a method for forming a photoresist pattern using the same wilt be described with reference to the accompanying drawings through various embodiments.

The terms and words used in the specification and claims should not be interpreted as being limited to typical meanings or dictionary definitions, but should be interpreted as having meanings and concepts relevant to the technical scope of the embodiments disclosed in the specification, based on the principle according to which the inventors can appropriately define the concept of the terms to describe their invention in the best manner.

In an embodiment of the invention, a composition for coating a photoresist pattern is provided which includes: a polymer compound represented by the following formula 1; and a solvent:

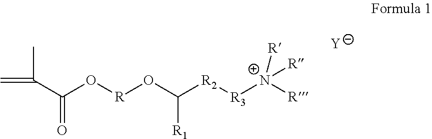

wherein R is a linear or branched hydrocarbon group having 1 to 20 carbon atoms, or a cyclic hydrocarbon group having 3 to 20 carbon atoms;
R₁ is hydrogen, a linear or branched hydrocarbon group having 1 to 5 carbon atoms or an oxygen atom, and when R₁ is an oxygen atom, it forms a double bond with a carbon atom;
R₂ is oxygen or a linear or branched hydrocarbon group having 1 to 5 in carbon atoms;
R₃ is a linear or branched hydrocarbon group having 1 to 5 carbon atoms;
each of R′, R″ and R′″ is independently hydrogen or a linear or branched hydrocarbon group having 1 to 5 carbon atoms; and
Y⁻ is an anion. For example, Y may be F⁻, Cl⁻, Br⁻, I⁻, NO₃⁻, HSO₄⁻, BF₄⁻, CN⁻, SO₃CF₃⁻, carbonate (COO⁻), sulfonate (SO₃⁻) sulfate (SO₄⁻), phosphonate (PO₃⁻), or phosphate (PO₄⁻).

Examples of a polymer compounds represented by formula 1 include compounds represented by the following formula 1a:

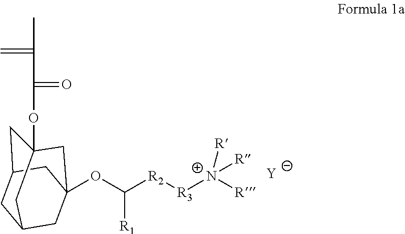

wherein R₁ is hydrogen, a linear or branched hydrocarbon group having 1 to 5 carbon atoms, or an oxygen atom and when R₁ is an oxygen atom, it forms a double bond with a carbon atom;
R₂ is oxygen or a linear or branched hydrocarbon group having 1 to 5 carbon atoms;
R₃ is a linear or branched hydrocarbon group having 1 to 5 carbon atoms;
R′, R″ and R′″ are each independently hydrogen or a linear or branched hydrocarbon group having 1 to 5 carbon atoms; and
Y⁻ is an anion. For example, Y may be F⁻, Cl⁻, Br⁻, I⁻, NO₃⁻, HSO₄⁻, BF₄⁻, CN⁻, SO₃CF₃⁻, carbonate (COO⁻), sulfonate (SO₃⁻), sulfate (SO₄⁻), phosphonate (PO₃⁻), or phosphate (PO₄⁻).

Examples of polymer compounds represented by formula 1a include compounds represented by the following formulas 1b or 1c:

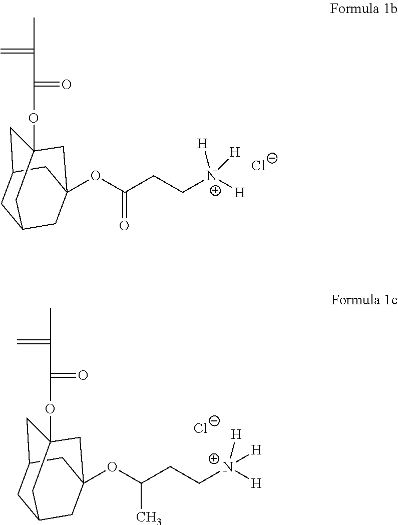 [SMILES: C=C(C)C(=O)OC12CC3CC(CC(OC(=O)CC[NH3+])(C3)C1)C2 ; [Cl-] ; C=C(C)C(=O)OC12CC3CC(C1)CC(OC(C)CC[NH3+])(C3)C2 ; [Cl-]]

The polymer compound may include an acrylic monomer containing an ammonium base as an end group. The polymer compound is protected by the ammonium base and soluble in water due to the ammonium base contained in the compound. The polymer compound may be deprotected by an acid catalyst generated from a photoacid generator in a photoresist pattern during a baking process and may be divided into an oil-soluble compound and a water-soluble compound according to the reaction scheme 1 shown below. The oil-soluble compound may then be cross-linked with a photosensitive polymer present on the surface of an underlying photoresist pattern during a baking process to reduce the size of the underlying photoresist pattern.

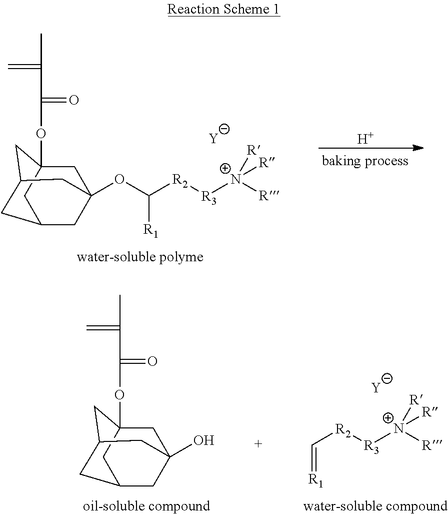

Meanwhile, the water-soluble compound does not form cross-links with the photosensitive polymer during the baking process and may be easily removed by an alkaline developer in a subsequent removal process. The thickness size and the like of the oil-soluble layer may be controlled by controlling the time and temperature of the baking process.

The photoresist pattern size may be effectively reduced below a conventional size, thereby allowing increased integration density of semiconductor circuits.

In the photoresist pattern coating composition according to the embodiment, the content of the polymer compound represented by formula 1 may be from about 0.1 to about 3 wt % based on the total weight of the photoresist pattern coating composition. If the content of the polymer compound is less than about 0.1 wt %, it may be difficult to form a coating layer on the underlying photoresist pattern. On the other hand, if the content of the polymer compound is more than about 3 wt %, the uniformity of the coating layer becomes poor.

In the photoresist pattern coating composition according to an embodiment of the invention, the solvent may include (i) an alcohol compound or (ii) a mixture of an alcohol compound and a surfactant.

The alcohol compound may include an alcohol selected from the group consisting of a C₁-C₁₀ alkylalcohol and a C₂-C₁₀ alkoxy alkylalcohol. Specifically, the C₁-C₁₀ alkylalcohol may include one or more selected from the group consisting of methanol, ethanol, propanol isopropanol, n-butanol, sec-butanol, t-butanol, 1-pentanol, 2-pentanol, 3-pentanol, and 2,2-dimethyl-1-propanol.

Furthermore, the C₂-C₁₀ alkoxy alkylalcohol may include one or more selected from the group consisting of 2-methoxyethanol, 2-(2-methoxyethoxy)ethanol, 1-methoxy-2-propanol, and 3-methoxy-1,2-propanoldiol.

A surfactant may be added to increase the coating property of the coating composition and to provide a uniform coating surface. The surfactant may be any suitable surfactant. For example, an anionic surfactant, a cationic surfactant or an amphoteric surfactant may be used alone or in a mixture of two or more thereof. The selection and amount of surfactant in the composition may affect the size and thickness of the photoresist pattern. More specific examples of the surfactant include alkylbenzene sulfonate surfactants, higher amine halides, quaternary ammonium surfactants, alkyl pyridinium surfactants, amino acid surfactants, sulfonimide surfactants, and the like.

The content of the surfactant is preferably from about 0.001 to about 0.1 wt % based on the total weight of the photoresist pattern coating composition.

In addition, the photoresist pattern coating composition may include other suitable additives such as an acid catalyst, a surfactant, a base and the like in order to improve resolution and coating properties.

For example, an acid catalyst may serve to increase the crosslinking density or rate during formation of the coating layer. For example, the acid catalyst may include hydrochloric acid, sulfuric acid, phosphoric acid, methylsulfonic acid, ethylsulfonic acid, propylsulfonic acid, butylsulfonic acid, benzenesulfonic acid, 2,4-dimethylbenzenesulfonic acid, p-toluenesulfonic acid (PTSA), camphorsulfonic acid, naphthylsulfonic acid, cyclohexylsulfonic add, acetic add, ethylacetic acid, propylacetic acid, isopropylacetic add, or mixtures thereof.

The surfactant serves to increase the coating property of the coating composition to thereby provide a uniform coating surface. The surfactant that is used in an embodiment may be a conventional surfactant. For example an anionic surfactant a cationic surfactant, an amphoteric surfactant or a mixture thereof may be used depending on a desired size and thickness of the photoresist pattern. More specific examples of the surfactant include alkylbenzene sulfonate surfactants, higher amine halides, quaternary ammonium surfactants alkyl pyridinium surfactants, amino acid surfactants, sulfonimide surfactants, or the like.

In addition, the base may serve as a crosslinker and a stabilizer. The base and may be an amine compound. For example, the base may be triethanolamine (TEOA), 2-aminoethanol, 2-(2-aminoethoxy)ethanol, or the like.

The concentration of the additives in the composition may preferably be from about 0.001 to about 0.1 wt % based on the total weight of the pattern coating composition. If the concentration of the additives is less than about 0.001 wt %, the effect of the additives may be insufficient and may affect the quality of the coating layer or may negatively affect the rate of crosslinking in the coating layer. If the content of the additives is more than about 0.1 wt %, the quality of the coating layer may become poor, or an excessive loss of the photoresist pattern can occur during formation of the coating layer, thereby deteriorating the condition of the surface of the photoresist pattern.

The photoresist pattern coating composition according to an embodiment of the invention may effectively reduce the size of a space or hole in the photoresist pattern by forming a uniform coating layer on the photoresist pattern., The photoresist pattern coating composition may:

(1) not damage a photoresist material and/or a layer pattern to be etched so that it can form a uniform coating layer when it is coated on an underlying photoresist pattern by a spin-coating technique;
(2) have excellent adhesion properties so as to form a thin layer on the surface of the photoresist pattern;
(3) have etching resistance similar to or higher than that of conventional photoresist materials;
(4) not form foams on the surface of the photoresist pattern when it is applied; and
(5) have an almost vertical profile(80-100°) after it is applied.

In another embodiment, a method for forming a fine pattern is provided the method including:

(a) forming a first photoresist pattern on a semiconductor substrate;
(b) coating the above-mentioned photoresist pattern coating composition on the first photoresist pattern;
(c) baking the photoresist pattern coated with the photoresist pattern coating composition to form a coating layer at the interface between the photoresist pattern and the photoresist pattern coating composition; and
(d) removing an unreacted portion of the photoresist pattern coating composition to form a second photoresist pattern.

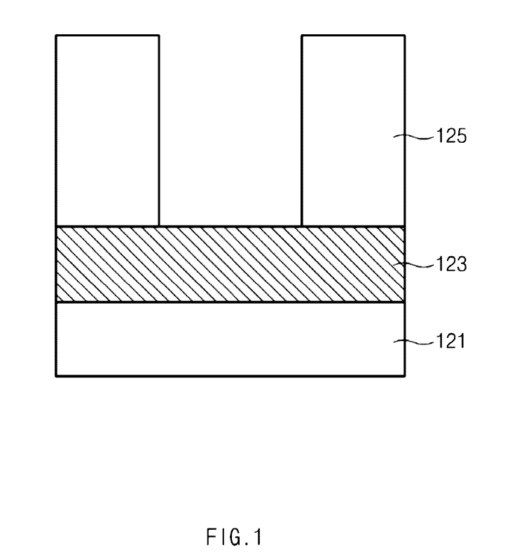

Hereinafter, embodiments will be described in detail with reference to the accompanying drawings. FIGS. 1 to 3 are schematic views illustrating a method for forming a fine pattern using a pattern coating composition according to an embodiment of the invention.

Referring to FIG. 1, an underlying layer 123 and a photoresist layer (not shown) are sequentially formed on a semiconductor substrate 121. An exposure and development process is performed to pattern the photoresist layer (not shown), thereby forming a first photoresist pattern 125. The material that used to form the photoresist layer is not specifically limited and may be any suitable conventional positive photoresist material or negative photoresist material. A positive photoresist material may preferably be used to form the photoresist layer.

The exposure process may preferably be performed with an exposure energy of about 0.1 to about 100 using KrF (248 nm), ArF 193 nm) VUV (157 nm), EUV (13 nm), E-beams, X-rays or ion beams as a light source.

In addition, the method may further include performing a soft baking process before the exposure process and performing a post baking process after the exposure process. The soft and post baking process may preferably be performed at a temperature ranging from about 70° C. to about 200° C.

The development process may be performed using an alkaline developer such as an aqueous solution containing from about 0.01 to about 5 wt % of tetramethylammanium hydroxide (TMAH).

The line width (CD) of the first photoresist pattern obtained by the development process may preferably be from about 30 to about 300 nm. According to an embodiment the line width (CD) of the first photoresist pattern obtained by the development process may be about 100 nm.

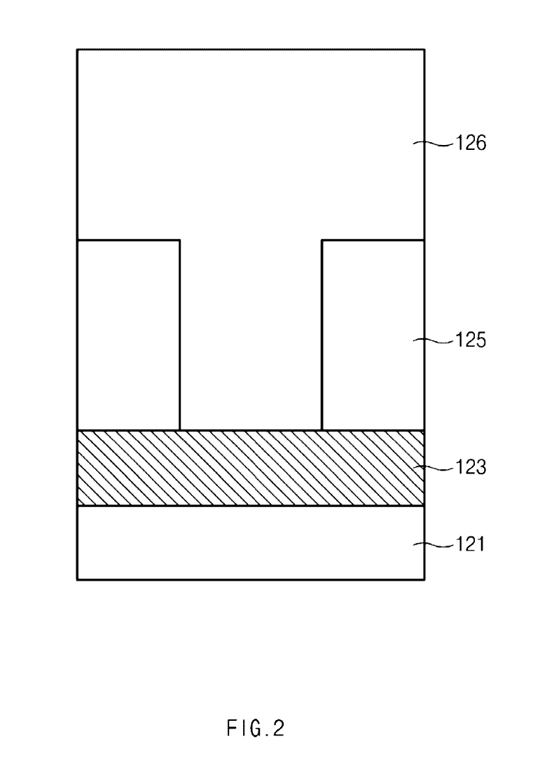

Next, referring to FIG. 2, the photoresist pattern coating composition as described above may be coated on the first photoresist pattern 125 by a spin-coating technique, thereby forming a photoresist pattern coating composition layer 126.

Herein, the photoresist pattern coating composition can be prepared by adding the compound of formula 1 and optionally additives to a solvent and filtering the mixture through a filter. In one embodiment a 0.2-μm filter may be used.

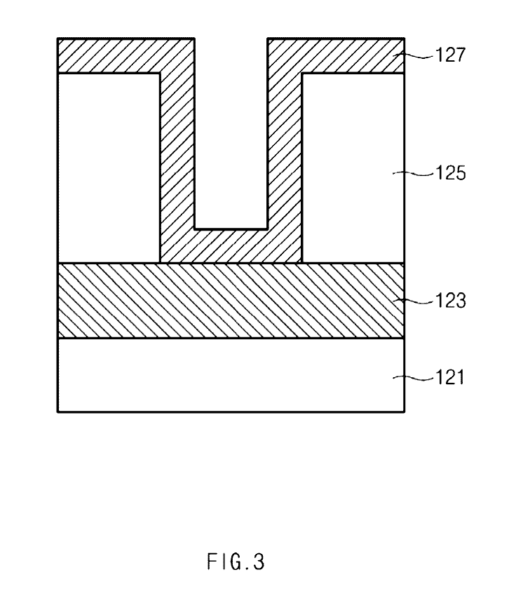

Next, referring to FIG. 3 in the fine pattern forming method according to an embodiment, the photoresist pattern having the photoresist pattern coating composition layer 126 coated thereon may be baked, thereby forming a coating layer 127 at the interface between the first photoresist pattern 125 and the photoresist pattern coating composition layer 126.

Then an unreacted portion of the photoresist pattern coating in composition layer 126, which does not form the coating layer, may be removed, thereby forming a second photoresist pattern 125/127 including the coating layer.

Herein, the baking may be performed at a temperature ranging from about 100° C. to about 200° C. According to an embodiment the baking may be performed at a temperature of about 150° C.

Removal of the photoresist pattern coating composition may be performed using water or a basic developer.

In an embodiment the second photoresist pattern 125/127 may have a line width that is about 10-40% greater than the line width of the first photoresist pattern 125. And, the space between two neighboring second photoresist patterns is a smaller than the space between two neighboring first photoresist patterns. For example, when a width ratio of the first photoresist pattern over a space between two neighboring first photoresist patterns is 1:1. For example the width ratio of the second photoresist pattern over a space between two neighboring second photoresist patterns may be 1:0.6-09.

The thickness of the coating layer may be from about 30 to about 3000 Å, In an embodiment the thickness of the coating layer may be particularly 1500 Å.

In still another embodiment, a device may be formed by using the fine pattern forming method described above. In the method, in coating layer containing the ammonium base-containing polymer compound may be used.

Hereinafter, examples will be described in detail. However, these examples are for illustrative purposes and are not intended to be restrictive.

### EXAMPLES

### I. Preparation of Photoresist Pattern Coating Composition

### Example 1

3.0 g of the polymer compound of formula 1b was added to 61 g of distilled water and mixed by stirring at room temperature for 1 minute. The mixture was filtered through a 0.2-μm filter to obtain a photoresist pattern coating composition according to an embodiment.

### Example 2

3.0 g of the polymer compound of formula 1c was added to 61 g of distilled water and mixed by stirring at room temperature for 1 minute. The mixture was filtered through a 0.2-μm filter to obtain a photoresist pattern coating composition according to an embodiment.

### II. Formation of Fine Pattern

### Comparative Example

### General Patterning Process

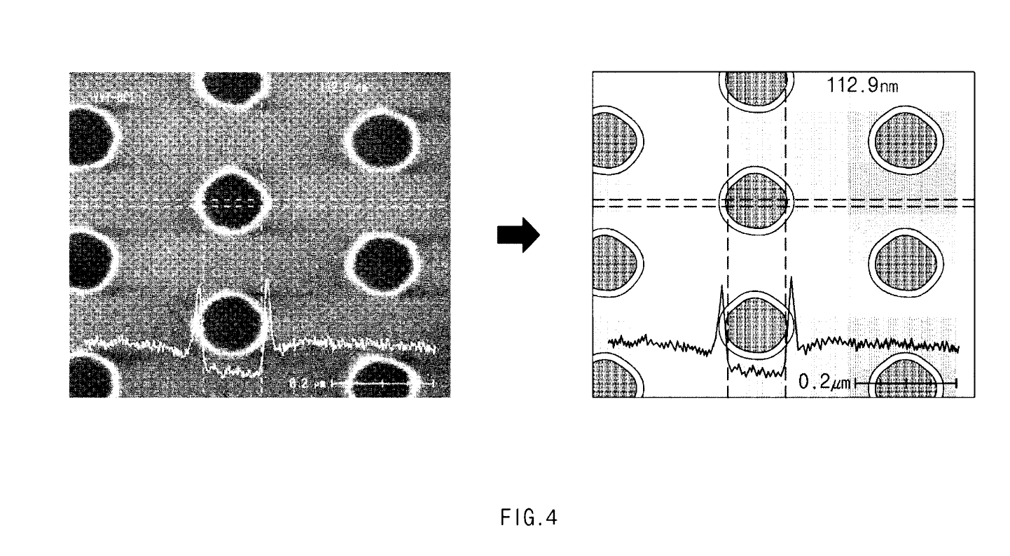

An organic anti-reflective coating (ARC) was applied to a silicon wafer treated with hexamethyldisilazane (HMDS) and methacrylate type photoresist (TarF-7a-39 manufactured by TOK) was s pin-coated thereon in to form a photoresist layer having a thickness of 3,500 Å. The photoresist layer was soft-baked in an oven at 130° C. for 90 seconds. After baking, the photoresist layer was exposed to light using an ArF laser exposure system and post-baked again in an oven at 130° C. for 90 seconds, After completion of baking, the photoresist layer was developed by dipping in an aqueous solution containing 2.38 wt % of TMAH for 30 seconds, thereby obtaining a 110-nm contact hole pattern (see FIG. 4).

### Example 3

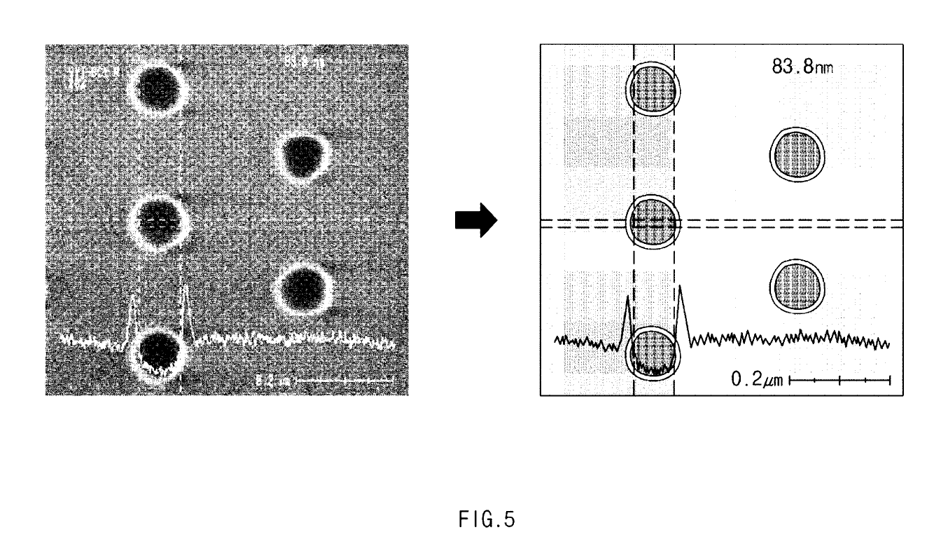

10 ml of the composition of the embodiment, prepared in Example 1 was spin-coated on the 110-nm contact hole pattern formed in the Comparative Example, after which it was baked at 150° C. and washed to remove an unreacted water-soluble compound. As a result, a contact hole pattern shrunk to 80 nm was obtained (see FIG. 5).

### Example 4

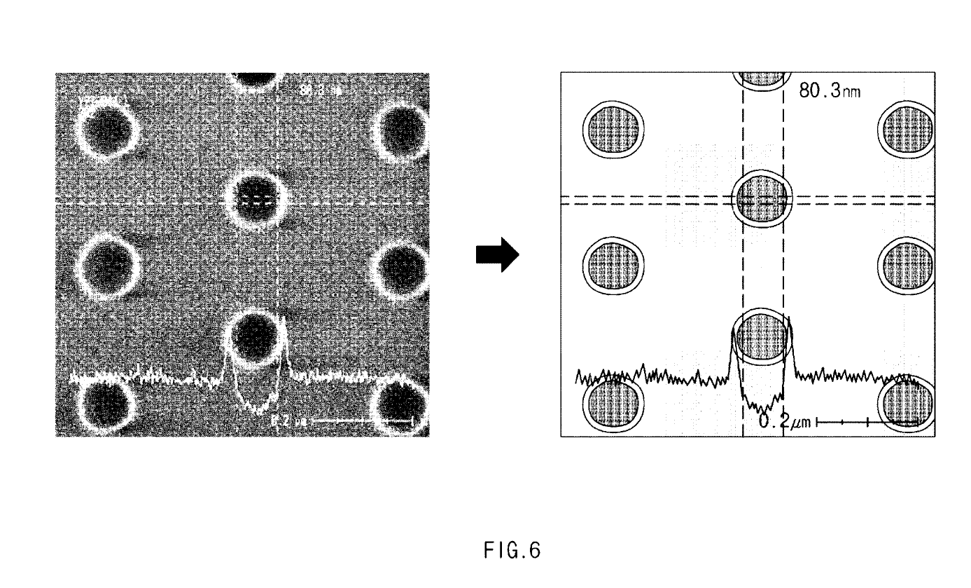

10 ml of the composition prepared in Example 2 was spin-coated on the 110-nm contact hole pattern formed in the Comparative Example and was baked at 150° C. and washed to remove an unreacted water-soluble compound. As a result, a contact hole pattern shrunk to 80 nm was obtained (see FIG. 6).

According to the embodiments as described above, a fine photoresist pattern having an effectively reduced space, e.g., an in effectively reduced contact hole or space size, can be formed in a simple manner by coating a photoresist pattern coating composition according to the embodiment on a general photoresist pattern. The photoresist pattern coating composition reacts with the general photoresist pattern. An unreacted material can be easily removed by an organic solvent during a development process which is performed after formation of the coating layer. Thus, no additional development is necessary and a mass production may be cost-effective. This method of the embodiment can be advantageously used in any semiconductor process in which a fine pattern in a size exceeding a given wavelength limit is formed.

While various embodiments have been described above, it will be understood to those skilled in the art that the embodiments described are by way of example only. Accordingly, the composition and method described herein should not be limited based on the described embodiments.

What is claimed is:

1. A composition for coating a photoresist pattern, comprising
a polymer compound and a solvent,
wherein the polymer compound is represented by the following formula 1: 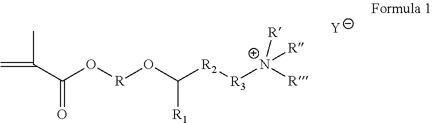
wherein R is a non-substituted or substituted, linear or branched hydrocarbon group having 1 to 20 carbon atoms or a non-substituted or substituted cyclic hydrocarbon group having 3 to 20 carbon atoms,
wherein R₁ is hydrogen, a linear or branched hydrocarbon group having 1 to 5 carbon atoms, or an oxygen atom, and when R₁ is an oxygen atom, it forms a double bond with a carbon atom,
wherein R₂ is oxygen or a linear or branched hydrocarbon group having 1 to 5 carbon atoms,
wherein R₃ is a linear or branched hydrocarbon group having 1 to 5 carbon atoms,
wherein each of R′, r″ and R′″ is independently hydrogen or a linear or branched hydrocarbon group having 1 to 5 carbon atoms, and
wherein Y⁻ is at least one anion selected from the group consisting of F⁻, Cl⁻, Br⁻, I⁻, NO₃⁻, HSO₄⁻, BF₄⁻, CN⁻, SO₃CF₃⁻, carbonate (COO⁻), sulfonate (SO₃⁻), sulfate (SO₄⁻), phosphonate (PO₃⁻), and phosphate (PO₄⁻).

2. The composition of claim 1, wherein the polymer compound is represented by the following formula 1a: 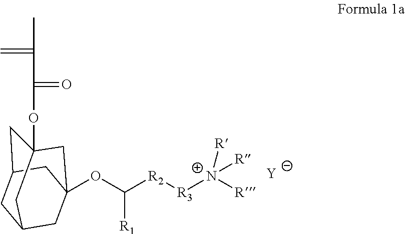
wherein R₁ is hydrogen, a linear or branched hydrocarbon group having 1 to 5 carbon atoms, or an oxygen atom, and when R₁ is an oxygen atom, it forms a double bond with a carbon atom,
wherein R₂ is oxygen or a linear or branched hydrocarbon group having 1 to 5 carbon atoms,
wherein R₃ is a linear or branched hydrocarbon group having 1 to 5 carbon atoms,
wherein each of R′, R″ and R′″ are each independently hydrogen or a linear or branched hydrocarbon group having 1 to 5 carbon atoms, and
Y⁻ is at least one anion selected from the group consisting of F⁻, Cl⁻, Br⁻, I⁻, NO₃⁻, HSO₄⁻, BF₄⁻, CN⁻, SO₃CF₃⁻, carbonate (COO⁻), sulfonate (SO₃⁻), sulfate (SO₄⁻), phosphonate (PO₃⁻), and phosphate (PO₄⁻).

3. The composition of claim 1, wherein the polymer compound is represented by the following formula 1b or 1c:

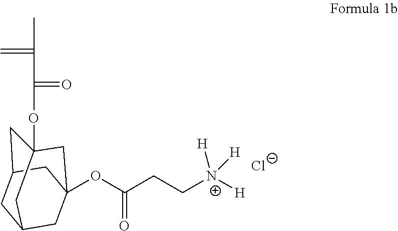 [SMILES: C=C(C)C(=O)OC12CC3CC(CC(OC(=O)CC[NH3+])(C3)C1)C2 ; [Cl-]]

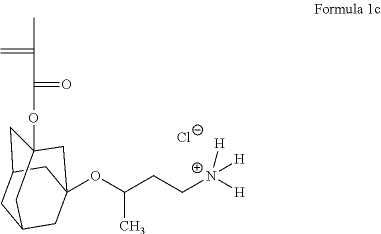 [SMILES: C=C(C)C(=O)OC12CC3CC(C1)CC(OC(C)CC[NH3+])(C3)C2 ; [Cl-]]

4. The composition of claim 1, wherein the polymer compound represented by formula 1 is contained in an amount of 0.1-3 wt % based on the total weight of the composition.

5. The composition of claim 1,
wherein the solvent comprises an alcohol, and
to wherein the composition further includes a surfactant.

6. The composition of claim 5, wherein the alcohol is selected from the group consisting of C₁-C₁₀ alkylalcohol, C₂-C₁₀ alkoxy alkylalcohol, and a combination thereof.

7. The composition of claim 6, wherein the C₁-C₁₀ alkylalcohol is selected from the group consisting of methanol, ethanol, propanol, isopropanol, n-butanol, sec-butanol, t-butanol, 1-pentanol, 2-pentanol, 3-pentanol, and 2,2-dimethyl-1-propanol, and a combination thereof.

8. The composition of claim 6, wherein the alkoxy alkylalcohol is selected from the group consisting of 2-methoxyethanol, 2-(2-methoxyethoxy)ethanol, 1-methoxy-2-propanol, 3-methoxy-1,2-propanoldiol, and a combination thereof.

9. The composition of claim 5, wherein the surfactant is contained in an amount of from 0.001 to 0.1 wt % based on the total weight of the composition.

10. A method for forming a fine pattern, comprising:
forming a first photoresist pattern over a underlying layer;
coating the composition of claim 1 over first photoresist pattern to form a composition layer;
baking the photoresist pattern and the composition to form a coating layer at an interface between the first photoresist pattern and the composition layer; and
removing an unreacted portion of the composition layer to form a second photoresist pattern,
wherein the second photoresist pattern comprises the coating layer and the first photoresist pattern, and
wherein a space between two neighboring second photoresist patterns is a smaller than a space between two neighboring first photoresist patterns.

11. The method of claim 10, wherein the baking is performed at a temperature ranging from 100° C. to 200° C.

12. The method of claim 10, wherein the removing of the unreacted portion of the composition layer is performed using water or an alkaline developer.

13. The method of claim 10, wherein the first photoresist pattern has a width of 30 to 300 nm.

14. The method of claim 10, wherein the second photoresist pattern has a width which is 10-40% greater than the width of the first photoresist pattern, and
wherein a space between two neighboring second photoresist patterns is a smaller than a space between two neighboring first photoresist patterns.

15. The method of claim 10, wherein the coating layer has a thickness of from 300 to 3000 Å.

16. A device comprising:
a substrate; and
a photoresist pattern formed over the substrate by the method of claim 10,
wherein the photoresist pattern is coated by a coating layer, and
wherein the coating layer comprises the compound represented by the formula 1.
